(19) United States
(12) Patent Application Publication
(10) Pub. No.: US 2012/0247811 A1
(43) Pub. Date: Oct. 4, 2012

(54) COMPOSITE CIRCUIT BOARD WITH FRACTURABLE STRUCTURE

(75) Inventors: GWUN-JIN LIN, TAOYUAN COUNTY (TW); KUO-FU SU, TAOYUAN COUNTY (TW); CHIH-HENG CHUO, TAOYUAN COUNTY (TW)

(73) Assignee: ADVANCED FLEXIBLE CIRCUITS CO., LTD., TAOYUAN COUNTY (TW)

(21) Appl. No.: 13/420,780

(22) Filed: Mar. 15, 2012

(30) Foreign Application Priority Data
Apr. 1, 2011 (TW) 100111474

(51) Int. Cl. H05K 1/00

(52) U.S. Cl. 174/251; 174/250; 174/254

(57) ABSTRACT

A composite circuit board with fracturable structure includes a first flat cable and first signal transmission lines formed on the first flat cable. A second flat cable is stacked on and bonded to the first circuit flat cable. The second flat cable includes second signal transmission lines and forms an overlapping segment and a selective breakable segment between which a fracturable structure is formed. The selective breakable segment covers the connection segment of the first flat cable or may be broken off for separation of the flat cables. Some of the second signal transmission lines of the second flat cable are connected through a hole in the first circuit flat cable to the first signal transmission lines of the first flat cable or connected through the hole to the conductive terminals of the connection segment of the first flat cable.

### BACKGROUND OF THE INVENTION

1. Field of the Invention

The present invention relates to the design of composite circuit board, and in particular to a composite circuit board with fracturable structure.

2. The Related Arts

In the progress of information and electronic industries, printed circuit boards play an extremely important role. The conventional flat cables are now getting phase out and the development of flexible printed circuit board greatly improves the technology level of the electronic industry. The flexible printed circuit is a technique that directly lays properly processed conductive traces on a flexible copper foil substrate. To accommodate the requirement for circuit capacity associated with the development of electrical and electronic products that is made compact, light-weighted, and highly integrated arrangement of electronic components, the printed circuit board is changed in such a way that an increasing number of layers are combined in a single circuit board to form a multiple printed circuit board in order to greatly expand the area where conductive traces can be laid. For example, mobile phones, notebook computers, and satellite navigation systems are illustrative applications of the multi-layer circuit boards.

The printed circuit boards or the flexible printed circuit boards each have their own advantages and characteristics and can be respectively used in different applications. The fast advance of modern electronic products makes the conventional printed circuit board or flexible printed circuit boards impotent in meeting the needs of the modern electronic products. Thus, it is desired to have a composite circuit board.

### SUMMARY OF THE INVENTION

To cope with such a desire for composite circuit board, a rigid-flex circuit board is disclosed in Taiwan Patent No. 133279 and U.S. Pat. No. 7,615,86082. These patents are generally workable for most requirements of the industries, yet the combination that can be made is limited. For example, for a combination of a multi-layer flexible printed circuit board, a single-sided printed circuit board, and a double-sided printed circuit board, there is still a technical gap to be filled. The present invention is thus made to overcome such a problem by providing a composite circuit board with fracturable structure that provides the industry with more options.

Thus, an object of the present invention is to provide a composite circuit board with fracturable structure, wherein the composite circuit board can be any of various combinations of multi-layer circuit board, single-sided printed circuit board, and double-sided printed circuit board.

Another object of the present invention is to provide a composite circuit board that facilitates manufacturing and future applications, wherein a fracturable structure is provided at a predetermined site, whereby a selective breakable segment that is a rigid section formed through the techniques of flexible circuit board in a manufacturing process can be selectively removed by a user in a future in order to satisfy the requirements of a specific application.

The solution adopted in the present invention to address the technical issues is that a first circuit flat cable is provided to stack on and bond to at least one second circuit flat cable. The second circuit flat cable forms an overlapping segment and a selective breakable segment, between which a fracturable structure is formed. The selective breakable segment is selectively set to cover the connection segment of the first circuit flat cable or broken off to allow the selective breakable segment of the second circuit flat cable and the first circuit flat cable to separate from each other.

Further, to meet the need for transmission of signals, a least one via hole extends through the first circuit flat cable. At least some of the second signal transmission lines of the second circuit flat cable are connected through the via hole to the first signal transmission lines of the first circuit flat cable or connected through the via hole to the conductive terminals of the connection segment of the first circuit flat cable.

In practical applications, the first circuit flat cable and the second circuit flat cable can be single-sided circuit boards, double-sided circuit boards, or multi-layered circuit board with multiple layers of substrate. The substrate can be a rigid board or a flexible board.

With the technical solution of the present invention, besides the various combinations of single-sided circuit boards, double-sided circuit boards, and multi-layered circuit board with multiple layers of substrate that can be used in a regular manufacturing process in a stacked form to make a composite circuit board, in a future use, the fracturable structure that is provided in the circuit board allows of selective removal of the selective breakable segment to meet various needs of circuit connection.

### BRIEF DESCRIPTION OF THE DRAWINGS

The present invention will be apparent to those skilled in the art by reading the following description of preferred embodiments of the present invention, with reference to the attached drawings, in which:

FIG. 1 is an exploded view showing a first embodiment of the present invention;

FIG. 2 is cross-sectional view illustrating a first circuit flat cable and a second circuit flat cable of the first embodiment of the present invention after being stacked together;

FIG. 3 is a perspective view showing spatial relationship between the first circuit flat cable and the second circuit flat cable of the first embodiment of the present invention to be stacked on each other;

FIG. 4 is a cross-sectional view showing a selective breakable segment of the second circuit flat cable removed from the first circuit flat cable of the first embodiment of the present invention;

FIG. 5 is another cross-sectional view showing a selective breakable segment of the second circuit flat cable removed from the first circuit flat cable of the first embodiment of the present invention;

FIG. 6 is a cross-sectional view showing the second circuit flat cable of the present invention being further bonded to a reinforcement layer to improve stiffness;

FIG. 7 is an exploded view showing a second embodiment of the present invention;

FIG. 8 is an exploded view showing a third embodiment of the present invention;

FIG. 9 is a cross-sectional view showing the third embodiment of the present invention in an assembled form;

FIG. 10 is an exploded view showing a fourth embodiment of the present invention; and

FIG. 11 is a cross-sectional view showing the fourth embodiment of the present invention in an assembled form.

### DETAILED DESCRIPTION OF THE PREFERRED EMBODIMENTS

With reference to the drawings and in particular to FIG. 1, which is an exploded view showing a first embodiment of the present invention, the present invention provides a composite circuit board with fracturable structure, generally designated at 100, which comprises a first circuit flat cable 1 in the form of a flat cable extending in an extension direction I and forming an overlapping segment A1 and a connection segment A2.

In the instant embodiment, the first circuit flat cable 1 comprises at least a substrate 11, a plurality of first signal transmission lines 12 formed on a first surface 11a of the substrate 11, and a first insulation cover layer 13 covering at least a portion of the first signal transmission lines 12.

At least some of the first signal transmission lines 12 have an end extending to the connection segment A2 to form a plurality of mutually isolated conductive terminals 121 spaced from each other by a predetermined distance.

At least a second circuit flat cable 2 is formed on and overlaps a second surface 11b of the first circuit flat cable 1 and also extends in the extension direction I and forms an overlapping segment A1′ and a selective breakable segment A2′.

The second circuit flat cable 2 comprises at least a substrate 21 and a plurality of second signal transmission lines 22 formed on a second surface (top surface) 21b of the substrate 21. The second signal transmission lines 22 that are laid on the second surface 21 b of the substrate 21 extends only within the overlapping segment A1′ or alternatively are allowed to extend to the selective breakable segment A2′. The second signal transmission lines 22 and the second surface 21b of the second circuit flat cable 2 may be covered with a second insulation cover layer 23.

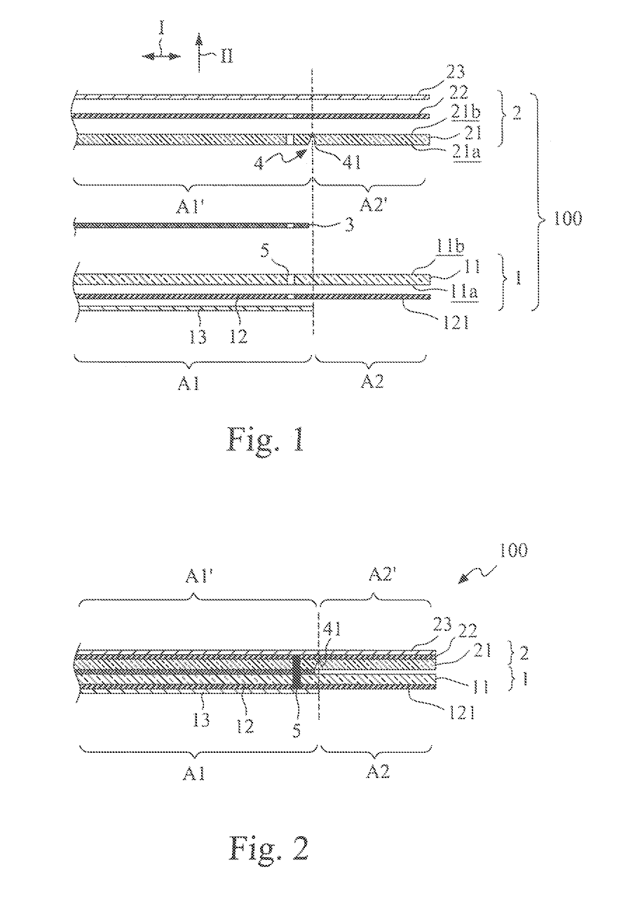

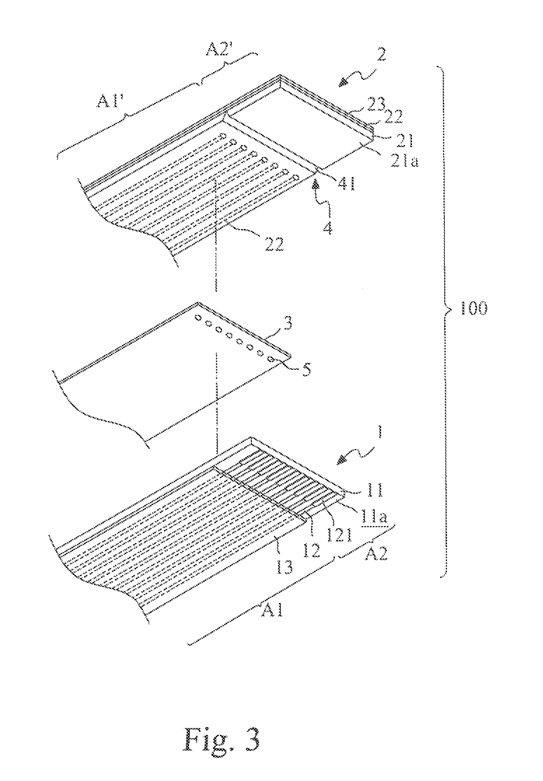

The second circuit flat cable 2 is arranged in such a way that the overlapping segment A1′ is stacked, with a first surface 21a thereof and in a direction substantially perpendicular to the extension direction I, on the second surface 11b of the overlapping segment A1 of the first circuit flat cable 1 and a bonding substance layer 3 is applied to bond and position the first circuit flat cable 1 and the second circuit flat cable 2 to each other. FIG. 2 is cross-sectional view illustrating the first circuit flat cable 1 and the second circuit flat cable 2 of the first embodiment of the present invention after being stacked together. FIG. 3 is a perspective view showing spatial relationship between the first circuit flat cable 1 and the second circuit flat cable 2 of the first embodiment of the present invention to be stacked on each other.

The second circuit flat cable 2 forms a fracturable structure 4 between the overlapping segment A1′ and the selective breakable segment A2′. The fracturable structure 4 comprises a notch 41 that is formed by cutting the first surface 21 a of the substrate 21 of the second circuit flat cable 2 in a normal direction II to a predetermined depth and the notch 41 extends from a side edge of the substrate 21 of the second circuit flat cable 2 to an opposite side edge. Alternatively, the fracturable structure 4 may comprises a breaking line form by applying laser energy (not shown) to the portion of the second circuit flat cable 2 between the overlapping segment A1′ and the selective breakable segment A2′ in such a way that the breaking line may extends from one side edge of the substrates 21 of the second circuit flat cable 2 to an opposite side edge.

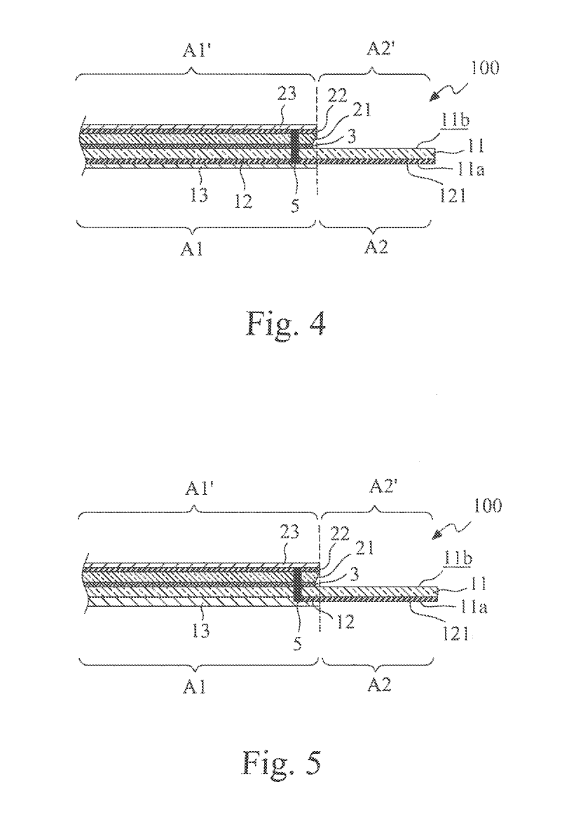

The selective breakable segment A2′ of the second circuit flat cable 2 overlaps the connection segment A2 of the first circuit flat cable 1. The selective breakable segment A2′ may be selectively set to cover the connection segment A2 of the first circuit flat cable 1 (as shown in FIG. 2) by being retained by the fracturable structure 4 or alternatively the selective breakable segment A2′ of the second circuit flat cable 2 may be removed from the first circuit flat cable 1 (as shown in FIG. 4) by breaking the fracturable structure 4.

At least one via hole 5 extends through the overlapping segment A1 of the first circuit flat cable 1 and the overlapping segment A1′ of the second circuit flat cable 2. At least some of the second signal transmission lines 22 are connected through the via holes 5 to at least some of the first signal transmission lines 12 of the first circuit flat cable 1 (as shown in FIG. 4). In another embodiment, the second signal transmission lines 22 may be connected through the via holes 5 to the first surface 11 a of the first circuit flat cable 1 to further connect to designated ones of the conductive terminals 121 of the connection segment A2 of the first circuit flat cable 1 (as shown in FIG. 5). In a practical structural arrangement, depending upon the requirements of lay-out of conductive lines, the via hole 5 can be a blind hole (which is a hole does not extend through the signal transmission lines) or a through hole (which is a hole extending through the signal transmission lines).

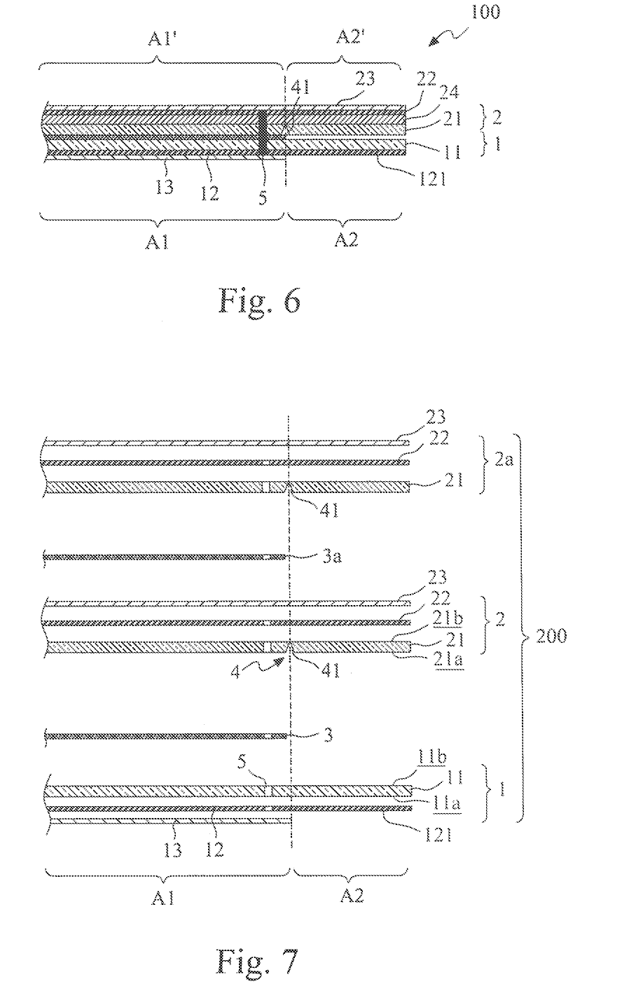

As to the material used, the first circuit flat cable 1 can be a circuit board comprising a single layer of substrate or a multi-layered circuit board comprising multiple layers of substrate. The substrate 11 can be a rigid board or a flexible board. The second circuit flat cable 2 can be a circuit board comprising a single layer of substrate or a multi-layered circuit board comprising multiple layers of substrate. The substrate 21 can be a rigid board or a flexible board. The second circuit flat cable 2 may be further bonded with a reinforcement layer 24 to improve the stiffness thereof (as shown in FIG. 6). The reinforcement layer 24 may be arranged on the second surface 21b of the substrate 21.

The description given above is made with respect to a single first circuit flat cable 1 and a single second circuit flat cable 2 as an illustrative example. In a composite circuit board with fracturable structure according to a second embodiment of the present invention, generally designated at 200, a single first circuit flat cable 1 and more than one second circuit flat cables 2, 2a are included (as shown in FIG. 7). In other words, one second circuit flat cable 2 is stacked on a second surface 11b of the first circuit flat cable 1 and another second circuit flat cable 2a is bonded to and positioned on the second circuit flat cable 2 by a bonding substance layer 3a.

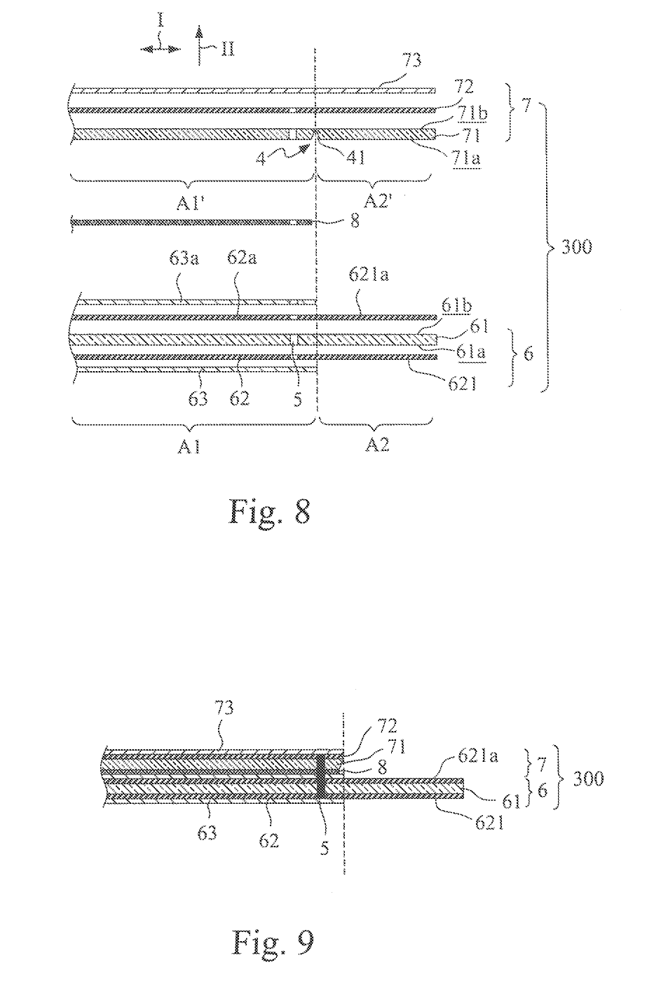

Besides being put into practice with a single-sided bard, the present invention may be applied to a double-sided board. As shown in FIGS. 8 and 9, a composite circuit board with fracturable structure according to a third embodiment of the present invention, generally designated at 300, comprises a first circuit flat cable 6 and at least one second circuit flat cable 7. The first circuit flat cable 6 is a double-sided circuit flat cable that is in the form of a flat cable extending in an extension direction I and forming an overlapping segment A1 and a connection segment A2.

The first circuit flat cable 6 comprises at least a substrate 61, a plurality of first signal transmission lines 62, 62a respectively formed on a first surface 11a and a second surface 61b of the substrate 11, and first insulation cover layers 63, 63a respectively covering at least a portion of the first signal transmission lines 62, 62a.

At least some of the first signal transmission lines 62, 62a have an end extending to the connection segment (free end) of the first circuit flat cable 6 to form a plurality of mutually isolated conductive terminals 621, 621a spaced from each other by a predetermined distance.

At least a second circuit flat cable 7 is bonded, in an overlapping manner, to the second surface 61b of the first circuit flat cable 6 by a bonding substance layer 8 and also extends in the extension direction I and forms an overlapping segment A1′ and a selective breakable segment A2′.

The second circuit flat cable 7 comprises at least a substrate 71 and a plurality of second signal transmission lines 72 formed on a second surface (to surface) 71b of the substrate 71. The second surface 71b and the second signal transmission lines 72 of the second circuit flat cable 7 may be covered with a second insulation cover layer 73.

The second circuit flat cable 7 and the first circuit flat cable 6 are stacked together in the same way as the previous embodiment. The second circuit flat cable 7 also comprises a fracturable structure 4 arranged between the overlapping segment A1′ and the selective breakable segment A2′. The selective breakable segment A2′ of the second circuit flat cable 7 may be selectively set to cover the connection segment A2 of the first circuit flat cable 6 by being retained by the fracturable structure 4 or alternatively the selective breakable segment A2′ of the second circuit flat cable 7 may be removed from the first circuit flat cable 6 by breaking the fracturable structure 4.

At least one via hole 5 extends through the overlapping segment A1 of the first circuit flat cable 6 and the overlapping segment A1′ of the second circuit flat cable 7. At least some of the second signal transmission lines 72 are connected through the via holes 5 to at least some of the first signal transmission lines 62 or 62a of the first circuit flat cable 6. The second signal transmission lines 72 may be connected through the via holes 5 to the first surface 61a or the second surface 61b of the first circuit flat cable 6 to further connect to designated ones of the conductive terminals 621a or 621b of the connection segment A2 of the first circuit flat cable 6.

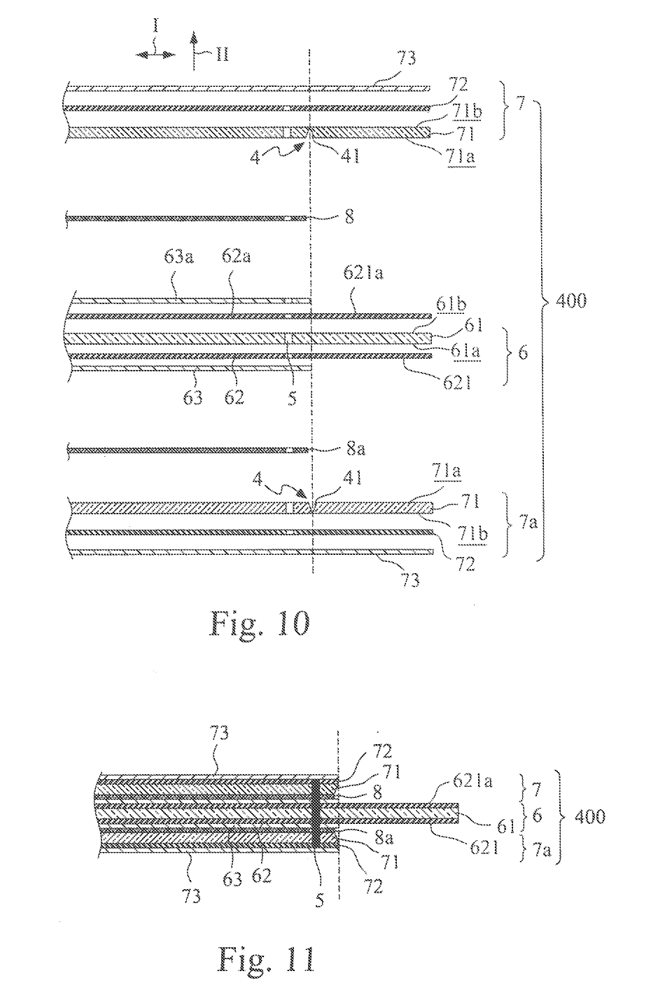

As shown in FIGS. 10 and 11, a composite circuit board with fracturable structure according to a fourth embodiment of the present invention, generally designated at 400, is a modification of the third embodiment shown in FIG. 8. Components/parts similar to those shown in FIG. 8 will bear the same reference numerous for consistency. A difference between these two embodiments is that the first circuit flat cable 6 has a bottom surface that is stacked on and bonded to a second circuit flat cable 7a by a bonding substance layer 8a. The second circuit flat cable 7a also comprises those components/elements discussed above, such as substrate 71, first surface 71a, second surface 71b, second signal transmission lines 72, second insulation cover layer 73, fracturable structure 4, via hole 5 and the likes.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A composite circuit board with fracturable structure, comprising:
a first circuit flat cable, which extends in an extension direction and forms an overlapping segment and a connection segment;
a plurality of conductive terminals, which is formed in the connection segment of the first circuit flat cable;
a plurality of first signal transmission lines, which is formed on the first circuit flat cable and extends to electrically connect with the conductive terminals of the connection segment;
at least one second circuit flat cable, which extends in the extension direction and forms an overlapping segment and a selective breakable segment, a fracturable structure being formed between the overlapping segment and the selective breakable segment, the overlapping segment of the second circuit flat cable being stacked in a stacking direction that is substantially perpendicular to the extension direction on the overlapping segment of the first circuit flat cable with the selective breakable segment being stacked on the connection segment of the first circuit flat cable, the selective breakable segment being selectively set to cover the connection segment of the first circuit flat cable or broken off to allow the selective breakable segment of the second circuit flat cable to separate from the first circuit flat cable;
a plurality of second signal transmission lines, which is formed on the second circuit flat cable;
a bonding substance layer, which is arranged between the first circuit flat cable and the second circuit flat cable to bond and position the first circuit flat cable and the second circuit flat cable with respect to each other; and
at least a via hole, which extends through the overlapping segment of the first circuit flat cable and the overlapping segment of the second circuit flat cable, at least a fraction of the second signal transmission lines of the second circuit flat cable being connected through the via hole to the first signal transmission lines of the first circuit flat cable.

2. The composite circuit board with fracturable structure as claimed in claim 1, wherein the first circuit flat cable comprises at least:
a substrate, which has a first surface and a second surface, the first signal transmission lines being formed on the first surface of the substrate; and
an insulation cover layer, which covers the first surface of the substrate and also cover at least a portion of the first signal transmission lines.

3. The composite circuit board with fracturable structure as claimed in claim 1, wherein the first circuit flat cable comprises at least:
a substrate, which has a first surface and a second surface, the first signal transmission lines being formed on the first surface and the second surface of the substrate; and
an insulation cover layer, which covers the first surface and the second surface of the substrate and also cover at least a portion of the first signal transmission lines.

4. The composite circuit board with fracturable structure as claimed in claim 1, wherein the first circuit flat cable comprises a multi-layered circuit board comprising multiple layers of substrate.

5. The composite circuit board with fracturable structure as claimed in claim 1, wherein the second circuit flat cable comprises at least:
a substrate, which has a first surface and a second surface, the second signal transmission lines being formed on the second surface of the substrate; and
an insulation cover layer, which covers the second surface of the substrate and also cover at least a portion of the second signal transmission lines.

6. The composite circuit board with fracturable structure as claimed in claim 1, wherein the first circuit flat cable comprises at least:
a substrate, which has a first surface and a second surface, the second signal transmission lines being formed on the first surface and the second surface of the substrate; and
an insulation cover layer, which covers the first surface and the second surface of the substrate and also cover at least a portion of the second signal transmission lines.

7. The composite circuit board with fracturable structure as claimed in claim 1, wherein the second circuit flat cable comprises a multi-layered circuit board comprising multiple layers of substrate.

8. The composite circuit board with fracturable structure as claimed in claim 1, wherein the substrate of the first circuit flat cable is a rigid board or a flexible board.

9. The composite circuit board with fracturable structure as claimed in claim 1, wherein the substrate of the second circuit flat cable is a rigid board or a flexible board.

10. The composite circuit board with fracturable structure as claimed in claim 1, wherein the fracturable structure comprises a notch that is formed by cutting the second circuit flat cable in a normal direction to a predetermined depth and extends from one side edge of the second circuit flat cable to an opposite side edge.

11. The composite circuit board with fracturable structure as claimed in claim 1, wherein the fracturable structure comprises a breaking line formed by applying laser to a portion of the second circuit flat cable between the overlapping segment and the selective breakable segment in such a way that the breaking line extends from one side edge of the second circuit flat cable to an opposite side edge.

12. The composite circuit board with fracturable structure as claimed in claim 1, wherein the second circuit flat cable is bonded to a reinforcement layer to improve stiffness.

13. The composite circuit board with fracturable structure as claimed in claim 1, wherein at least some of the second signal transmission lines of the second circuit flat cable are connected through the via hole to the conductive terminals of the connection segment of the first circuit flat cable.
